(19) United States
(12) Patent Application Publication
(10) Pub. No.: US 2025/0212631 A1
(43) Pub. Date: Jun. 26, 2025

(54) STRETCHABLE DISPLAY DEVICE

(71) Applicant: LG Display Co., Ltd., Seoul (KR)

(72) Inventors: Hae-Yoon JUNG, Paju-si (KR); Myung-Sub LIM, Paju-si (KR); Yu-Ra JEONG, Paju-si (KR); In-Jun LEE, Paju-si (KR)

(21) Appl. No.: 18/918,715

(22) Filed: Oct. 17, 2024

(30) Foreign Application Priority Data
Dec. 21, 2023 (KR) 10-2023-0187886

(51) Int. Cl. H10K 59/131; H10K 102/00

(52) U.S. Cl. CPC H10K 59/131; H10K 2102/311

(57) ABSTRACT

A display device includes: first and second substrates facing and spaced apart from each other; a plurality of third substrates on an inner surface of the first substrate; a plurality of vertical lines between two of the plurality of third substrates adjacent to each other along a first direction; a plurality of horizontal lines between two of the plurality of third substrates adjacent to each other along a second direction crossing the first direction; a plurality of vertical connection lines connecting a first side of one of the plurality of third substrates and the plurality of vertical lines; a plurality of horizontal connection lines connecting a second side adjacent to the first side of the one of the plurality of third substrates and the plurality of horizontal lines; and a plurality of light emitting diodes on the plurality of third substrates, respectively.

### CROSS-REFERENCE TO RELATED APPLICATION

The present application claims the priority benefit of Republic of Korea Patent Application No. 10-2023-0187886, filed in Republic of Korea on Dec. 21, 2023, which is hereby incorporated by reference in its entirety.

### BACKGROUND

### Technical Field

The present disclosure relates to a display device, and more particularly, to a stretchable display device where a stretch rate is improved by connecting a connection line to two sides of a rigid part.

### Description of the Related Art

Recently, with the advent of an information-oriented society, the interest in information displays for processing and displaying a massive amount of information and the demand for portable information media have increased. As such, a display field has rapidly advanced. Thus, various light and thin flat panel display devices have been developed and highlighted.

With the progress of a display-related technology, a flexible display device where a shape is changed by folding, bending or rolling has been researched and developed. Specifically, a stretchable display device where a display element and a conductive line are disposed on a substrate of a flexible material such as a plastic has been the subject as a next generation display device. The stretchable display device is stretchable along a predetermined direction to be changed to various shapes.

The stretchable display device includes a rigid part where a pixel is disposed and a soft part where a connection line connecting pixels is disposed. Since the rigid part is not stretched, a strain higher than a stretch rate of an entire display panel may be applied to the soft part.

Further, since an area of the soft part is may decrease and an area of the rigid part may increase for a relatively high resolution, a strain applied to the soft part further increases.

### BRIEF SUMMARY

The present disclosure is directed to a stretchable display device that, among others, substantially obviates one or more of the problems due to limitations and disadvantages of the related art.

The present disclosure provides a stretchable display device where a strain applied to a soft part is reduced by disposing a horizontal line and a vertical line between adjacent rigid parts and connecting the horizontal line and the vertical line to two sides of the rigid part.

The present disclosure provides a stretchable display device where a strain applied to a soft part is reduced, an area of a rigid part increases, and adjacent light emitting diodes have a uniform distance by classifying the adjacent rigid parts as a rigid part group, disposing a horizontal line and a vertical line between adjacent rigid parts, connecting the horizontal line and the vertical line to two sides of the rigid part and disposing the light emitting diode at a corner of the rigid part group.

Additional features and characteristics of the disclosure will be set forth in the description which follows, and in part will be apparent from the description, or can be learned by practice of the disclosure. These and other features of the disclosure will be realized and attained by the structure pointed out in the written description, as examples, and claims hereof as well as the appended drawings.

To achieve these and other technical characteristics and in accordance with the embodiments of the present disclosure, as embodied and broadly described herein, a display device includes: first and second substrates facing and spaced apart from each other; a plurality of third substrates on an inner surface of the first substrate, the plurality of third substrates spaced apart from each other; a plurality of vertical lines between two of the plurality of third substrates adjacent to each other along a first direction; a plurality of horizontal lines between two of the plurality of third substrates adjacent to each other along a second direction crossing the first direction; a plurality of vertical connection lines connecting a first side of one of the plurality of third substrates and the plurality of vertical lines; a plurality of horizontal connection lines connecting a second side adjacent to the first side of the one of the plurality of third substrates and the plurality of horizontal lines; and a plurality of light emitting diodes on the plurality of third substrates, respectively.

It is to be understood that both the foregoing general description and the following detailed description are explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a perspective view showing a stretchable display device according to a an embodiment of the present disclosure;

FIG. 2 is a plan view showing a display panel of a stretchable display device according to a an embodiment of the present disclosure;

FIG. 3 is a circuit diagram showing a subpixel of a display panel of a stretchable display device according to a an embodiment of the present disclosure;

FIG. 4 is a cross-sectional view taken along a line IV-IV of FIG. 2;

FIG. 5 is a cross-sectional view taken along a line V-V of FIG. 2;

FIGS. 6A and 6B are each a cross-sectional view showing a crossing portion of a display panel of a stretchable display device according to a an embodiment of the present disclosure; and

FIG. 7 is a plan view showing a display panel of a stretchable display device according to a an embodiment of the present disclosure.

### DETAILED DESCRIPTION

Technical characteristics and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device,” and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of moisture or oxygen into the emitting element layer. In addition, a layer on the array may include an inorganic light emitting layer, for example, a nano-sized material layer or a quantum dot.

The thin film transistor of the present disclosure may include one of an oxide thin film transistor, an amorphous silicon thin film transistor, a low temperature polycrystalline silicon thin film transistor.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

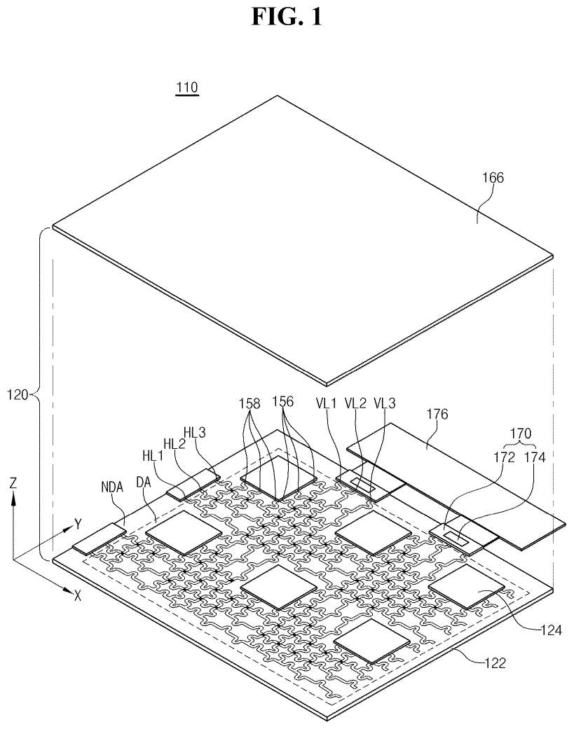

FIG. 1 is a perspective view showing a stretchable display device according to an embodiment of the present disclosure. The stretchable display device may be an organic light emitting diode (OLED) display device.

In FIG. 1, a stretchable display device 110 according to an embodiment of the present disclosure includes a display panel 120, a flexible printed circuit (FPC) 170 and a printed circuit board (PCB) 176.

The display panel 120 may be stretched along a first direction X and/or a second direction Y. The first direction X and the second direction Y cross each other to constitute a plane of the stretchable display device 110.

The display panel 120 includes first (or base) and second (or cap) substrates 122 and 166 facing and spaced apart from each other in a third direction Z, and a plurality of third substrates (or unit substrate) 124 on an inner surface of the first substrate (or base substrate) 122 that faces the second substrate 166 along the third direction Z. The first and second substrates 122 and 166 may each include a soft material having bendable and stretchable property, and the plurality of third substrates 124 may include a rigid material.

In some embodiments, a display panel 120 includes only the first (base) substrate 122 and the third (unit) substrates 124 and does not include the second (top) substrate 166. Instead, transparent encapsulation materials or layers may be formed over the third (unit) substrates 124.

The plurality of third substrates 124 may be spaced apart from each other, e.g., in the X-Y plane, to each have an island shape.

The first substrate 122 includes a display area DA for displaying an image and a non-display area NDA adjacent to the display area DA or surrounding the display area DA.

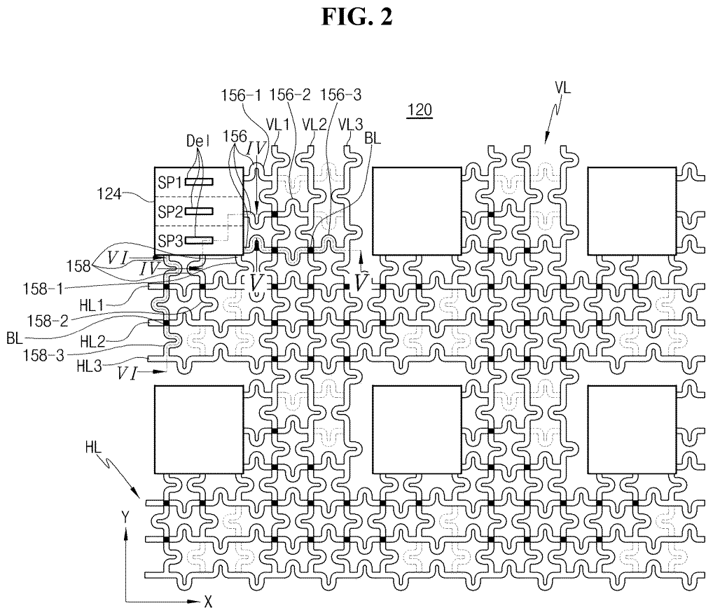

The display area DA includes a plurality of pixels each including a plurality of subpixels SP1 to SP3 (of FIG. 2), and the plurality of pixels may correspond to the plurality of third substrates 124, respectively.

Each of the plurality of subpixels SP1 to SP3 includes circuits units such as a light emitting diode, and a plurality of voltage lines such as a gate line, a data line, a high level line and a low level line may be connected to each of the plurality of subpixels SP1 to SP3.

The non-display area NDA does not display an image. A plurality of link lines extending from the plurality of voltage lines disposed in the display area DA and a plurality of pads connected to ends of the plurality of link lines may be disposed in the non-display area NDA.

The display area DA and the non-display area NDA may be classified into a rigid part which corresponds to the plurality of third substrates 124 and is not stretchable and a soft part which corresponds to the first substrate 122 except for the plurality of third substrates 124 and is stretchable.

The flexible printed circuit 170 may include a base film 172 of a soft material, a driving integrated circuit (IC) 174 mounted on the base film 172 and a plurality of conductive lines connected to the driving integrated circuit 174. The driving integrated circuit 174 generates a gate signal and a data signal for displaying an image and transmits the gate signal and the data signal to the display panel 120. The plurality of conductive lines transmits a plurality of signals.

Although the flexible printed circuit 170 has a chip on film (COF) type in an embodiment of FIG. 1, the flexible printed circuit 170 may have a chip on glass (COG) type or a tape carrier package (TCP) type in an embodiment.

The printed circuit board 176 includes a circuit part for controlling the driving integrated circuit 174. For example, the printed circuit board 176 may include a timing controlling unit which generates a plurality of control signals using an image signal and a plurality of timing signals from an external system and transmits the plurality of control signals to the driving integrated circuit 174.

In the stretchable display device 110, a strain applied to the soft part may be reduced by connecting a plurality of connection lines to only two sides among four sides of each of the plurality of third substrates 124.

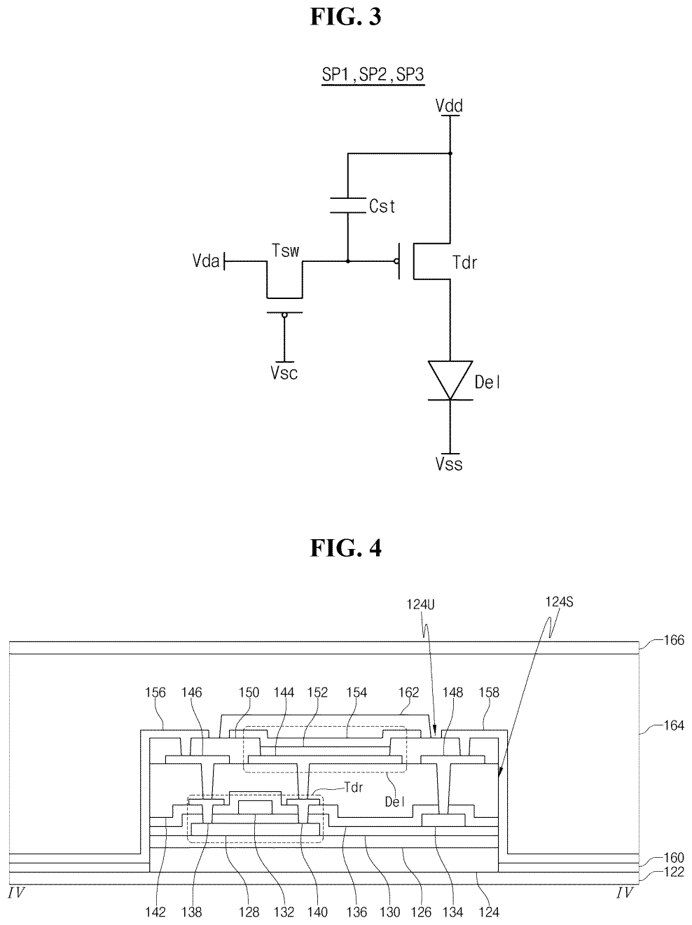

FIG. 2 is a plan view showing a display panel of a stretchable display device according to an embodiment of the present disclosure, and FIG. 3 is a circuit diagram showing a subpixel of a display panel of a stretchable display device according to a an embodiment of the present disclosure.

In FIG. 2, the display panel 120 of the stretchable display device 110 according an embodiment of the present disclosure includes a plurality of third substrates 124, a plurality of vertical lines VL (including VL1, VL2 and VL3 shown) disposed between two of the plurality of third substrates 124 adjacent to each other along the first direction X, a plurality of horizontal lines HL (including HL1, HL2 and HL3 shown) disposed between two of the plurality of third substrates 124 adjacent to each other along the second direction Y crossing the first direction X, a plurality of vertical connection lines 156 each connecting a third substrate 124 of the plurality of third substrates 124 and a vertical line VL of the plurality of vertical lines VL (VL1, VL2 and VL3) and a plurality of horizontal connection lines 158 each connecting a third substrate of the plurality of third substrates 124 and a horizontal line HL of the plurality of horizontal lines HL (HL1, HL2 and HL3).

Each of the plurality of third substrates 124 includes first, second and third subpixels SP1, SP2 and SP3 constituting a pixel, and each of the first, second and third subpixels SP1, SP2 and SP3 includes the light emitting diode Del.

In some implementations, each of the plurality of third substrates 124 may have a tetragonal shape, although other shapes are also possible for the third substrates 124 and are included in the scope of the disclosure.

In FIG. 3, each of the first, second and third subpixels SP1, SP2 and SP3 includes a switching transistor Tsw, a driving transistor Tdr, a storage capacitor Cst and the light emitting diode Del, and each of the switching transistor Tsw and the driving transistor Tdr may be a P-type transistor.

A gate electrode of the switching transistor Tsw is connected to a gate voltage Vsc, a source electrode of the switching transistor Tsw is connected to a data voltage Vda, and a drain electrode of the switching transistor Tsw is connected to a gate electrode of the driving transistor Tdr and a first capacitor electrode of the storage capacitor Cst.

A gate electrode of the driving transistor Tdr is connected to a drain electrode of the switching transistor Tsw and the first capacitor electrode of the storage capacitor Cst, a source electrode of the driving transistor Tdr is connected to a high level voltage Vdd and a second capacitor electrode of the storage capacitor Cst, and a drain electrode of the driving transistor Tdr is connected to a first electrode (anode) of the light emitting diode Del.

The first electrode of the light emitting diode Del is connected to the drain electrode of the driving transistor Tdr, and a second electrode (cathode) of the light emitting diode Del is connected to a low level voltage Vss.

In each of the first, second and third subpixels SP1, SP2 and SP3, when the switching transistor Tsw is turned on according to the gate voltage Vsc, the data voltage Vda is applied to the gate electrode of the driving transistor Tdr. When the driving transistor Tdr is turned on according to the data voltage Vda, a current corresponding to the data voltage Vda is supplied to the light emitting diode Del due to the high level voltage Vdd and the low level voltage Vss, and the light emitting diode Del emits a light corresponding to the data voltage Vda. The storage capacitor Cst stores the data voltage Vda to maintain a voltage of the gate electrode of the driving transistor Tdr for one frame.

Although each of the first, second and third subpixels SP1, SP2 and SP3 has a 2T1C structure including two transistors and one capacitor in an example embodiment of FIG. 3, each subpixel may have other configurations like one or more of 4T1C, 5T1C, 3T2C, 4T2C, 5T2C, 6T2C, 7T1C, 7T2C, 8T1C and 8T2C structures in some embodiments.

In FIG. 2, the plurality of vertical lines VL1, VL2 and VL3 are spaced apart from each other and are each disposed along the second direction Y and configured to transmit a plurality of pixel driving voltages for driving the light emitting diode Del in one or more third substrates 124 arranged along the second direction Y, and the plurality of horizontal lines HL1, HL2 and HL3 are spaced apart from each other and are each disposed long the first direction X and configured to transmit the plurality of pixel driving voltages for driving the light emitting diode Del in one or more third substrates 124.

For example, the plurality of vertical lines may include first, second and third vertical lines VL1, VL2 and VL3, and the first, second and third vertical lines VL1, VL2 and VL3 may transmit the red, green and blue data voltages Vda, respectively. The plurality of horizontal lines may include first, second and third horizontal lines HL1, HL2 and HL3, and the first, second and third horizontal lines HL1, HL2 and HL3 may transmit the gate voltage Vsc, the high level voltage Vdd and the low level voltage Vss, respectively.

In some embodiments, the plurality of vertical lines may include first, second, third and fourth vertical lines, and the first, second, third and fourth vertical lines may transmit red, green and blue data voltages and a reference voltage, respectively. The plurality of horizontal lines may include first, second, third and fourth horizontal lines, and the first, second, third and fourth horizontal lines may transmit a gate voltage, a high level voltage, a low level voltage and an emission voltage, respectively.

Each of the plurality of vertical lines VL1, VL2 and VL3 and the plurality of horizontal lines HL1, HL2 and HL3 may have a wave shape, a diamond shape or a zigzag shape.

Each of the plurality of vertical connection lines 156 may be connected between a same first side, e.g., a right side of each third substrate 124 of the plurality of third substrates 124 and a vertical line VL of the plurality of vertical lines VL1, VL2 and VL3 along the first direction X to transmit the plurality of pixel driving voltages of the plurality of vertical lines VL1, VL2 and VL3 to each of the plurality of third substrates 124.

For example, the plurality of vertical connection lines 156 may include first, second and third vertical connection lines 156-1, 156-2, 156-3. The first vertical connection line 156-1 may be connected to the first vertical line VL1 and the first subpixel SP1 to transmit the red data voltage Vda of the first vertical line VL1 to the first subpixel SP1, the second vertical connection line 156-2 may be connected to the second vertical line VL2 and the second subpixel SP2 to transmit the green data voltage Vda of the second vertical line VL2 to the second subpixel SP2, and the third vertical connection line 156-3 may be connected to the third vertical line VL3 and the third subpixel SP3 to transmit the blue data voltage Vda of the third vertical line VL3 to the third subpixel SP3. A bridge layer BL is disposed in a crossing portion of the vertical connection line 156 and the vertical line VL1, VL2 and VL3.

The first vertical connection line 156-1 may be connected to the first vertical line VL1. The second vertical connection line 156-2 may cross the first vertical line VL1 in an electrically insulated state from the first vertical line VL1 to be connected to the second vertical line VL2. The third vertical connection line 156-3 may cross the first and second vertical lines VL1 and VL2 in an electrically insulated state from the first and second vertical lines VL1 and VL2 to be connected to the third vertical line VL3.

Each of the plurality of horizontal connection lines 158 may be connected between a same second side, e.g., a bottom side adjacent to the right side of each of the plurality of third substrates 124 and the plurality of horizontal lines HL1, HL2 and HL3 along the second direction Y to transmit the plurality of pixel driving voltages of the plurality of horizontal lines HL1, HL2 and HL3 to each of the plurality of third substrates 124.

For example, the plurality of horizontal connection lines 158 may include first, second and third horizontal connection lines 158-1, 158-2, 158-3. The first horizontal connection line 158-1 may be connected to the first horizontal line HL1 and the first, second and third subpixels SP1, SP2 and SP3 to transmit the gate voltage Vsc of the first horizontal line HL1 to the first, second and third subpixels SP1, SP2 and SP3, the second horizontal connection line 158-2 may be connected to the second horizontal line HL2 and the first, second and third subpixels SP1, SP2 and SP3 to transmit the high level voltage Vdd of the second horizontal line HL2 to the first, second and third subpixels SP1, SP2 and SP3, and the third horizontal connection line 158-3 may be connected to the third horizontal line HL3 and the first, second and third subpixels SP1, SP2 and SP3 to transmit the low level voltage Vss of the third horizontal line HL3 to the first, second and third subpixels SP1, SP2 and SP3.

The first horizontal connection line 158-1 may be connected to the first horizontal line HL1. The second horizontal connection line 158-2 may cross the first horizontal line HL1 in an electrically insulated state from the first horizontal line HL1 to be connected to the second horizontal line HL2. The third horizontal connection line 158-3 may cross the first and second horizontal lines HL1 and HL2 in an electrically insulated state from the first and second horizontal lines HL1 and HL2 to be connected to the third horizontal line HL3.

Each of the plurality of vertical connection lines 156 and the plurality of horizontal connection lines 158 may have a wave shape, a diamond shape or a zigzag shape.

In an embodiment, the plurality of vertical connection lines 156 may be connected to the right side of each of the plurality of third substrates 124, and the plurality of horizontal connection lines 158 may be connected to a top side adjacent to the right side of each of the plurality of third substrates 124. Alternatively or additionally, the plurality of vertical connection lines 156 may be connected to a left side of each of the plurality of third substrates 124, and the plurality of horizontal connection lines 158 may be connected to a bottom side adjacent to the left side of each of the plurality of third substrates 124. Alternatively or additionally, the plurality of vertical connection lines 156 may be connected to a left side of each of the plurality of third substrates 124, and the plurality of horizontal connection lines 158 may be connected to a top side adjacent to the left side of each of the plurality of third substrates 124. In some implementations, the plurality of vertical connection lines 156 are each connected to a same first side of the plurality of third substrates 124, and the plurality of horizontal connection lines are each connected to a same second side of the plurality of third substrates. The first side and the second side meet one another.

The horizontal lines and the vertical lines are disposed between the adjacent rigid parts, e.g., the third substrate 124, and two sides of the rigid part are connected to the horizontal line and the vertical line through the connection line. As a result, the adjacent rigid parts have at least one side not connected to and spaced apart from the horizontal lines and the vertical lines, and the strain applied to the soft part, e.g., the first substrate 122, is reduced.

FIG. 4 is a cross-sectional view taken along a line IV-IV of FIG. 2, and FIG. 5 is a cross-sectional view taken along a line V-V of FIG. 2. FIG. 4 shows a structure of the rigid part, and FIG. 5 shows a connection structure of the vertical connection line and the vertical line.

In FIG. 4, the display panel 120 of the stretchable display device 110 according to a an embodiment of the present disclosure includes the first and second substrates 122 and 166 facing and spaced apart from each other.

The plurality of third substrates 124 spaced apart from each other along the first and second directions X and Y are disposed in the display area DA on the inner surface of the first substrate 122. The first substrate 122 supports and protects elements of the display panel 120, and the plurality of third substrates 124 supports and protects elements of the plurality of subpixels SP1, SP2 and SP3.

Although not shown, an adhesive layer may be disposed between the first substrate 122 and the plurality of third substrates 124, and the plurality of third substrates 124 may be fixed to the first substrate 122 due to the adhesive layer.

The first substrate 122 is formed of a soft material having bendable and stretchable property, and the soft material may include one or more of a silicone rubber such as polydimethylsiloxane (PDMS), an elastomer such as polyurethane (PU) or styrene butadiene styrene (SBS).

For example, the first substrate 122 may have a Young's modulus of 1 MPa to 999 MPa, a ductile failure rate over about 100% and a thickness of about 10 μm to about 1 mm.

The third substrate 124 is formed of a rigid material having a stretch lower than the soft material of the first substrate 122, and the rigid material may include one of a resin of polyimide (PI) group and a resin of epoxy group.

For example, the third substrate 124 may have a Young's modulus equal to or greater than 1000 times of the Young's modulus of the first substrate 122.

Accordingly, the first substrate 122 and the third substrate 124 have different rigidity and different Young's modulus from each other. An area corresponding to the third substrate 124 constitutes the rigid part, and an area corresponding to the first substrate 122 of a portion except for the third substrate 124 constitutes the soft part. A rigidity of the rigid part may be greater than a rigidity of the soft part.

A buffer layer 126 is disposed on the third substrate 124. The buffer layer 126 blocks a permeation of moisture or oxygen to protect the elements of the plurality of subpixels SP1, SP2 and SP3.

The buffer layer 126 has a single layer or a multiple layer of an inorganic insulating material, and the inorganic insulating material may include silicon nitride (SiNx), silicon oxide (SiOx) and silicon oxynitride (SiON).

To prevent a damage such as a crack of the buffer layer 126 due to a stretch (elongation), the buffer layer 126 may be patterned to correspond to the third substrate 124 and may be disposed only on the third substrate 124.

In some embodiments, the buffer layer 126 may be omitted.

A semiconductor layer 128 is disposed on the buffer layer 126 in each of the first, second and third subpixels SP1, SP2 and SP3, and a gate insulating layer 130 is disposed on the semiconductor layer 128 over the entire third substrate 124.

The semiconductor layer 128 may include a channel region at a central portion thereof and source and drain regions at both sides of the channel region.

For example, the semiconductor layer 128 may be formed of a semiconductor material such as polycrystalline silicon, and the gate insulating layer 130 may be formed of an inorganic insulating material such as silicon nitride (SiNx), silicon oxide (SiOx) and silicon oxynitride (SiON).

To prevent a damage such as a crack of the gate insulating layer 130 due to a stretch, the gate insulating layer 130 may be patterned to correspond to the third substrate 124 and may be disposed only on the third substrate 124.

A gate electrode 132 is disposed on the gate insulating layer 130 corresponding to the semiconductor layer 128, and a gate pad 134 is disposed on the gate insulating layer 130 spaced apart from the gate electrode 132. The gate pad 134 may be connected to the gate electrode of the switching transistor Tsw.

The gate electrode 132 and the gate pad 134 may have the same layer and the same material as each other. For example, the gate electrode 132 and the gate pad 134 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

An interlayer insulating layer 136 is disposed on the gate electrode 132 and the gate pad 134 over the entire third substrate 124, and a source electrode 138 and a drain electrode 140 spaced apart from each other are disposed on the interlayer insulating layer 136.

The interlayer insulating layer 136 may be formed of an inorganic insulating material such as silicon oxide (SiOx) and silicon oxynitride (SiON).

To prevent a damage such as a crack of the interlayer insulating layer 136 due to a stretch, the interlayer insulating layer 136 may be patterned to correspond to the third substrate 124 and may be disposed only on the third substrate 124.

The source electrode 138 and the drain electrode 140 are connected to the source region and the drain region, respectively, of the semiconductor layer 128 through contract holes in the interlayer insulating layer 136 and the gate insulating layer 130.

The source electrode 138 and the drain electrode 140 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

The semiconductor layer 128, the gate electrode 132, the source electrode 138 and the drain electrode 140 constitute the driving transistor Tdr, and the switching transistor Tsw may have the same cross-sectional structure as the driving transistor Tdr.

A planarizing layer 142 is disposed on the source electrode 138 and the drain electrode 140 over the entire third substrate 124, and a first electrode 144, a data pad 146 and a connection pad 148 spaced apart from each other are disposed on the planarizing layer 142.

The planarizing layer 142 may have a single layer or a multiple layer of an organic insulating material such as acrylic resin and benzocyclobutene (BCB).

The first electrode 144 is connected to the drain electrode 140 through a contact hole in the planarizing layer 142, the data pad 146 is connected to the source electrode 138 through a contact hole in the planarizing layer 142, and the connection pad 148 is connected to the gate pad 134 through a contact hole in the planarizing layer 142 and the interlayer insulating layer 136.

The first electrode 144, the data pad 146 and the connection pad 148 may have the same layer and the same material as each other. For example, the first electrode 144, the data pad 146 and the connection pad 148 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

A bank layer 150 is disposed on the first electrode 144, the data pad 146 and the connection pad 148 over the entire third substrate 124. The bank layer 150 covers an edge portion of the first electrode 144 and has an open portion exposing a central portion of the first electrode 144.

An emitting layer 152 is disposed on the first electrode 144 exposed through the open portion of the bank layer 152. The emitting layer 150 may include a hole assisting layer such as a hole injecting layer and a hole transporting layer, an emitting material layer and an electron assisting layer such as an electron transporting layer and an electron injecting layer.

A second electrode 154 is disposed on the emitting layer 152 and the bank layer 150 adjacent to the open portion, and the vertical connection line 156 and the horizontal connection line 158 spaced apart from each other are disposed on the bank layer 150.

The second electrode 154 may be formed of a transparent conductive material such as indium tin oxide (ITO) and indium zinc oxide (IZO), and the vertical connection line 156 and the horizontal connection line 158 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

The first and second electrodes 144 and 154 may be an anode and a cathode, respectively, and the first electrode 144, the emitting layer 152 and the second electrode 154 constitute the light emitting diode Del.

The vertical connection line 156 is connected to the data pad 146 through a contact hole in the bank layer 150, and the horizontal connection line 158 is connected to the connection pad 148 through a contact hole in the bank layer 150.

The vertical connection line 156 and the horizontal connection line 158 extend from the third substrate 124 of the rigid part to the soft part to be connected to the vertical lines VL1, VL2 and VL3 and the horizontal lines HL1, HL2 and HL3, respectively, on the first substrate 122. A damage preventing layer 160 may be disposed between the vertical and horizontal connection lines 156 and 158 and the first substrate 122 and between the vertical and horizontal lines VL1, VL2, VL3, HL1, HL2 and HL3 and the first substrate 122. Each of the vertical connection line 156 and the horizontal connection line 158 may extends from a top surface 124U of the third substrate 124, along a side surface 124S of the third substrate 124, and beyond the third substrate 124 on top of the damage protection layer 160.

Although not shown, an adhesive layer may be disposed between the damage preventing layer 160 and the first substrate 122, and the damage preventing layer 160 may be fixed to the first substrate 122 due to the adhesive layer.

The damage preventing layer 160 may be disposed on the first substrate 122 to correspond to a shape of each of the vertical lines VL1, VL2 and VL3 and the horizontal lines HL1, HL2 and HL3 in the soft part.

The damage preventing layer 160 may correspond to the vertical connection line 156, the horizontal connection line 158, the vertical line VL1, VL2 and VL3 and the horizontal line HL1, HL2 and HL3 to have one of a wave shape, a diamond shape and a zigzag shape.

The damage preventing layer 160 may be formed of a rigid material such as one of a resin of polyimide (PI) group and a resin of epoxy group. The damage preventing layer 160 may have the same material and the same thickness as the third substrate 124.

The damage preventing layer 160 of a rigid material has the same shape as the vertical connection line 156, the horizontal connection line 158, the vertical line VL1, VL2 and VL3 and the horizontal line HL1, HL2 and HL3 and is disposed under the vertical connection line 156, the horizontal connection line 158, the vertical line VL1, VL2 and VL3 and the horizontal line HL1, HL2 and HL3. As a result, when the display panel 120 is stretched, a breakdown of the vertical connection line 156, the horizontal connection line 158, the vertical line VL1, VL2 and VL3 and the horizontal line HL1, HL2 and HL3 is prevented, and an over-stretching of the first substrate 122 is prevented.

In an embodiment, the damage preventing layer 160 may be omitted, and the vertical connection line 156, the horizontal connection line 158, the vertical line VL1, VL2 and VL3 and the horizontal line HL1, HL2 and HL3 may directly contact the first substrate 122.

An encapsulating layer 162 is disposed on the second electrode 154. The encapsulating layer 162 covers the light emitting diode Del and contacts a top surface of the bank layer 150 to encapsulate the light emitting diode Del. As a result, a permeation of a moisture or an oxygen of an exterior may be prevented.

The encapsulating layer 162 may have a single layer of an inorganic insulating material or a multiple layer where an inorganic insulating material and an organic insulating material are alternately laminated.

The encapsulating layer 162 may be disposed to selectively cover the second electrode 154 of the third substrate 124, and the encapsulating layers 162 of the plurality of third substrates 124 may be spaced apart from each other.

As a result, when the display panel 120 is stretched, a damage of the encapsulating layer 162 is minimized and reduction in reliability of the light emitting diode Del is prevented.

An adhesive layer 164 and the second substrate 166 are sequentially disposed on the encapsulating layer 162, the vertical connection line 156 and the horizontal connection line 158.

The second substrate 166 may be formed of the same material as the first substrate 122 and may be attached to the first substrate 122 due to the adhesive layer 164.

For example, the second substrate 166 may include one of a silicone rubber such as polydimethylsiloxane (PDMS), an elastomer such as polyurethane (PU) and styrene butadiene styrene (SBS).

Although each subpixel SP1, SP2 and SP3 includes the light emitting diode Del of an organic material in an embodiment of FIG. 4, each subpixel SP1, SP2 and SP3 may include a micro light emitting diode in some embodiments.

In FIG. 5, the damage preventing layer 160 is selectively disposed in the soft part on the first substrate 122 of the display panel 120 of the stretchable display device 110 according to an embodiment of the present disclosure to correspond to the vertical connection line 156 and the vertical line VL1, VL2 and VL3.

Although not shown, the damage preventing layer 160 may be selectively disposed in the soft part on the first substrate 122 to correspond to the horizontal connection line 158 and the horizontal line HL1, HL2 and HL3.

A bridge layer BL is disposed in a crossing portion of the vertical connection line 156 and the vertical line VL1, VL2 and VL3 on the damage preventing layer 160.

As shown in FIG. 2, a bridge layer BL may be disposed in a crossing portion of the horizontal connection line 158 and the horizontal line HL1, HL2 and HL3 on the damage preventing layer 160.

The bridge layer BL may have a circular shape or a polygonal shape and may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

A cross insulating layer 155 is disposed on the bridge layer BL. The cross insulating layer 155 may have a circular shape or a polygonal shape covering both end portions of the bridge layer BL along the first direction X and exposing both end portions of the bridge layer BL along the second direction Y. The cross insulating layer 155 may be formed of an inorganic insulating material or an organic insulating material.

The vertical lines VL1, VL2 and VL3 are disposed on the cross insulating layer 155 along the second direction Y, and the vertical connection line 156 is disposed on the damage preventing layer 160.

The vertical connection line 156 (156-3 shown as an illustrative example) extends along the first direction X from the third substrate 124 to the first vertical line VL1 to contact the bridge layer BL exposed outside one side of the cross insulating layer 155 under the first vertical line VL1. The third vertical connection line 156-3 does not contact and is insulated from the first vertical line VL1 due to the cross insulating layer 155 under the first vertical line VL1.

The vertical connection line 156 contacts the bridge layer BL exposed outside the other side of the cross insulating layer 155 under the first vertical line VL1 and extends along the first direction X from the first vertical line VL1 to the second vertical line VL2 to contact the bridge layer BL exposed outside one side of the cross insulating layer 155 under the second vertical line VL2. The third vertical connection line 156-3 does not contact and is insulated from the second vertical line due to the cross insulating layer 155 under the second vertical line VL2.

In some implementations, the third vertical connection line 156-3 extends partially on the cross insulating layer 155 under the first vertical line VL1 and on the cross insulating layer 155 under the second vertical line VL2. As such, the third vertical connection line 156-3 may be at a same level as the first vertical line VL1 and the second vertical line VL2.

The vertical connection line 156 contacts the bridge layer BL exposed outside the other side of the cross insulating layer 155 under the second vertical line VL2 and extends along the first direction X from the second vertical line VL2 to the third vertical line VL3 to be connected to the third vertical line VL3.

The vertical lines VL1, VL2 and VL3 and the vertical connection line 156 may have the same layer and the same material as each other and may cover two sides of the cross insulating layer 155.

As shown in FIG. 2, the first vertical connection line 156-1 is connected between the first side (shown as right side on FIG. 2) of each the third substrate 124 of the plurality of third substrates and the first vertical line VL1 without the bridge layer therebetween.

The second vertical connection line 156-2 is connected between the first side of each the third substrate 124 of the plurality of third substrates and one a first side BLS1 of the bridge layer BL under the first vertical line V11 and between a second side BLS2 of the bridge layer BL under the first vertical line VL1 and the second vertical line VL2.

The third vertical connection line 156-3 is connected between the first side of each the third substrate 124 of the plurality of third substrates and the first side BLS1 of the bridge layer BL under the first vertical line VL1, between a second side BLS2 of the bridge layer BL under the first vertical line VL1 and a first side BLS1 of the bridge layer BL under the second vertical line VL2 and between a second side BLS2 of the bridge layer BL under the second vertical line and the third vertical line VL3.

Although not specifically shown, the horizontal lines HL1, HL2 and HL3 are disposed on the cross insulating layer 155 along the first direction X, and the horizontal connection line 158 is disposed on the damage preventing layer 160.

The horizontal connection line 158 extends along the second direction Y from the third substrate 124 to the first horizontal line HL1 to contact the bridge layer BL exposed outside one side of the cross insulating layer 155 under the first horizontal line HL1 and to contact the bridge layer BL exposed outside the other side of the cross insulating layer 155 under the first horizontal line HL1. The horizontal connection line 158 extends along the second direction Y from the first horizontal line HL1 to the second horizontal line HL2 to contact the bridge layer BL exposed outside one side of the cross insulating layer 155 under the second horizontal line HL2 and to contact the bridge layer BL exposed outside the other side of the cross insulating layer 155 under the second horizontal line HL2. The horizontal connection line 158 extends along the second direction Y from the second horizontal line HL2 to the third horizontal line HL3 to be connected to the third horizontal line HL3.

The horizontal lines HL1, HL2 and HL3 and the horizontal connection line 158 may have the same layer and the same material as each other and may cover both sides of the cross insulating layer 155.

Similarly as shown in FIG. 5, the third vertical connection line of the plurality of vertical connection lines 156 is connected to the third vertical line VL3. The second vertical connection line of the plurality of vertical connection lines 156 may cross the first vertical line VL1 through contact with the bridge layer BL under the first vertical line VL1 and may be connected to the second vertical line VL2. The first vertical connection line of the plurality of vertical connection lines 156 may be directly connected to the first vertical line VL1 without contact with the bridge layer BL.

Although the second vertical connection line of the plurality of vertical connection lines 156 extends to the second vertical line VL2 to be connected to the second vertical line VL2, the damage preventing layer 160 under the second vertical connection line may extend to the third vertical line VL3 through the second vertical line VL2 to be connected to the damage preventing layer 160 under the third vertical line VL3. The extending portion of the damage preventing layer 160 may be shown as a dotted line in FIG. 2.

Although the plurality of vertical connection lines 156 extends to one of the first, second and third vertical lines VL1, VL2 and VL3, the damage preventing layer 160 under the plurality of vertical connection lines 156 may extend to the third vertical line VL3 to be connected to the damage preventing layer 160 under the third vertical line VL3. As a result, the damage preventing layer 160 may be disposed as a matrix shape in the entire display panel 120 and a structural stability of the damage preventing layer 160 may be improved.

The damage preventing layer 160 may extend to one of the first, second and third vertical lines VL1, VL2 and VL3 the same as the plurality of vertical connection lines 156.

Although not shown, the second horizontal connection line of the plurality of horizontal connection lines 158 may cross the first horizontal line HL1 through contact with the bridge layer BL under the first horizontal line HL1 to be connected to the second horizontal line HL2. The first horizontal connection line of the plurality of horizontal connection lines 158 may be directly connected to the first horizontal line HL1 without contact with the bridge layer BL.

Similarly to the plurality of vertical connection lines 156, although the plurality of horizontal connection lines 158 extend to one of the first, second and third horizontal lines HL1, HL2 and HL3, the damage preventing layer 160 under the plurality of horizontal connection lines 158 extends to the third horizontal line HL3 to be connected to the damage preventing layer 160 under the third horizontal line HL3. As a result, the damage preventing layer 160 may be disposed as a matrix shape in the entire display panel 120 and a structural stability of the damage preventing layer 160 may be improved.

The damage preventing layer 160 may extend to one of the first, second and third horizontal lines HL1, HL2 and HL3 the same as the plurality of horizontal connection lines 158.

The plurality of vertical lines VL1, VL2 and VL3 and the plurality of horizontal lines HL1, HL2 and HL3 may cross each other using the cross insulating layer 155 and the bridge layer BL to maintain the connection.

In an embodiment, the vertical line and the vertical connection line may have different layers.

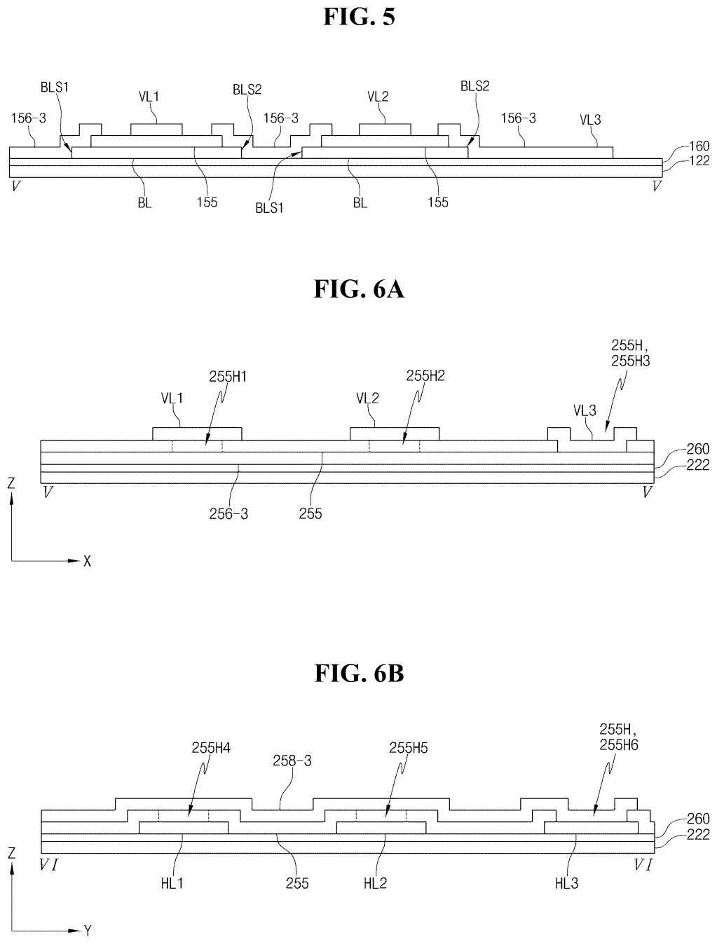

FIG. 6A is a cross-sectional view showing a crossing portion of a display panel of a stretchable display device according to a an embodiment of the present disclosure. FIG. 6A corresponds to a line V-V of FIG. 2 and illustrations on the same part as the an embodiment may be omitted.

In FIG. 6A, a damage preventing layer 260 is selectively disposed in a soft part of a display panel of a stretchable display device according to a an embodiment of the present disclosure to correspond to a vertical connection line 256 and a plurality of vertical lines VL1, VL2 and VL3.

Although not shown, the damage preventing layer 260 may be selectively disposed in the soft part on a first substrate 222 to correspond to a horizontal connection line and a plurality of horizontal lines HL1, HL2 and HL3.

The vertical connection line 256 is disposed on the damage preventing layer 260 and extends along a first direction X from a third substrate to the third vertical line VL3.

Although not shown, the plurality of horizontal lines may be disposed on the damage preventing layer 260 and may extend along a first direction X from the third substrate.

A cross insulating layer 255 is disposed on the vertical connection line 256. The cross insulating layer 255 completely covers both sides of the vertical connection line 256 along the second direction Y and has a hole or opening 255H3 exposing the vertical connection line 256-3 corresponding to the third vertical line VL3. The cross insulating layer 255 may include an inorganic insulating material or an organic insulating material. The cross insulating layer 255 also has contact holes or openings 255H1, 255H2 (shown in dotted lines) exposing the vertical connection lines 156-1 or 156-2 for connecting to the first vertical line VL1 and the second vertical line VL2, respectively.

As shown in FIG. 6B, the cross insulating layer 255 is disposed on the plurality of horizontal lines HL1, HL2 and HL3. The cross insulating layer 255 may completely cover both sides of the plurality of horizontal lines HL1, HL2 and HL3 along the second direction Y and may have a contact hole 255H6 exposing the third horizontal line HL3 (holes 255H4, 255H5 exposing the first horizontal line HL1, the second horizontal line HL2, respectively). A horizontal connection line 258 (third horizontal connection line 258-3 shown) is on the cross insulting layer 255 and is connected to the corresponding horizontal line HL (HL3 shown) through the respective hole 255H (255H6 shown).

As shown in FIG. 6A, the plurality of vertical lines VL1, VL2 and VL3 are disposed on the cross insulating layer 255 along the second direction Y. The first and second vertical lines VL1 and VL2 are electrically insulated from the vertical connection line 256 due to the cross insulating layer 255, and the third vertical line VL3 is electrically connected to the vertical connection line 256 through a contact hole in the cross insulating layer 255.

The vertical connection line 256 and the plurality of vertical lines VL1, VL2 and VL3 may have different layers from each other.

As shown in FIG. 6B, the horizontal connection line is disposed on the cross insulating layer 255 along the second direction Y. The horizontal connection line is electrically insulated from the first and second horizontal lines HL1 and HL2 due to the cross insulating layer 255, and the horizontal connection line is electrically connected to the third horizontal line HL3 through a contact hole in the cross insulating layer 255.

The horizontal connection line and the plurality of horizontal lines HL1, HL2 and HL3 may have different layers from each other.

In FIG. 6A, the third vertical connection line of the plurality of vertical connection lines 256 is connected to the third vertical line VL3 through a hole or opening 255H3 in the cross insulation line 255. The second vertical connection line of the plurality of vertical connection lines 256 may cross the first vertical line VL1 with the cross insulating layer 255 interposed therebetween and may be connected to the second vertical line VL2 through a contact hole 255H2 in the cross insulating layer 255. The first vertical connection line of the plurality of vertical connection lines 256 may be connected to the first vertical line VL1 through a contact hole 255H1 in the crossing insulating layer 255.

Although the second vertical connection line of the plurality of vertical connection lines 256 extends to the second vertical line VL2 to be connected to the second vertical line VL2, the damage preventing layer 260 under the second vertical connection line may extend to the third vertical line VL3 through the second vertical line VL2 to be connected to the damage preventing layer 260 under the third vertical line VL3. The extending portion of the damage preventing layer 260 may be shown as a dotted line in FIG. 2.

Although the plurality of vertical connection lines 256 extends to one of the first, second and third vertical lines VL1, VL2 and VL3, the damage preventing layer 260 under the plurality of vertical connection lines 256 may extend to the third vertical line VL3 to be connected to the damage preventing layer 260 under the third vertical line VL3. As a result, the damage preventing layer 260 may be disposed as a matrix shape in the entire display panel and a structural stability of the damage preventing layer 260 may be improved.

In an embodiment, the damage preventing layer 260 may extend to one of the first, second and third vertical lines VL1, VL2 and VL3 the same as the plurality of vertical connection lines 256.

FIGS. 5 and 6A show as examples the cross-section views of the vertical lines and VL the vertical connections lines 156. The same or similar cross-section views as FIGS. 5 and 6 may also apply to the horizontal lines HL and horizontal connection lines 158 in some implementations, which could be different from or in additional to the implementations shown in FIG. 6B of the horizontal lines HL and horizontal connection lines.

As shown in FIG. 6B, the second horizontal connection line of the plurality of horizontal connection lines may cross the first horizontal line with the crossing insulating layer 255 interposed therebetween to be connected to the second horizontal line through a contact hole in the crossing insulating layer 255. The first horizontal connection line of the plurality of horizontal connection lines may be connected to the first horizontal line through a contact hole in the crossing insulating layer 255.

Similarly to the plurality of vertical connection lines 256, although the plurality of horizontal connection lines extend to one of the first, second and third horizontal lines, the damage preventing layer 260 under the plurality of horizontal connection lines HL extends to the third horizontal line to be connected to the damage preventing layer 260 under the third horizontal line. As a result, the damage preventing layer 260 may be disposed as a matrix shape in the entire display panel and a structural stability of the damage preventing layer 260 may be improved.

In an embodiment, the damage preventing layer 260 may extend to one of the first, second and third horizontal lines the same as the plurality of horizontal connection lines.

The plurality of vertical lines VL1, VL2 and VL3 and the plurality of horizontal lines HL1, HL2 and HL3 cross each other with the crossing insulating layer 255 interposed therebetween to maintain the connection.

In the display device according to first and an embodiments of the present disclosure, the plurality of vertical lines VL1, VL2 and VL3 are disposed between the third substrates 124 of the rigid part adjacent to each other along the first direction X, and the plurality of horizontal lines HL1, HL2 and HL3 are disposed between the third substrates 124 of the rigid part adjacent to each other along the second direction Y. The plurality of vertical connection lines 156 connect a first side of the third substrate 124 of the rigid part and the plurality of vertical lines VL1, VL2 and VL3, and the plurality of horizontal connection lines 158 connect a second side of the third substrate 124 of the rigid part and the plurality of horizontal lines HL1, HL2 and HL3. Since the adjacent rigid parts are not connected to the horizontal line and the vertical line and have at least one side spaced apart from the horizontal line and the vertical line, a strain applied to the soft part is reduced and a stretch rate is maximized.

For example, when the display panel 120 is stretched by about 20%, each of the rigid part and the soft part may be stretched by about 20%. As a result, a stretch reliability is improved.

In an embodiment, four adjacent rigid parts may be classified into one rigid part group, and a horizontal line and a vertical line may be disposed between the adjacent rigid part groups.

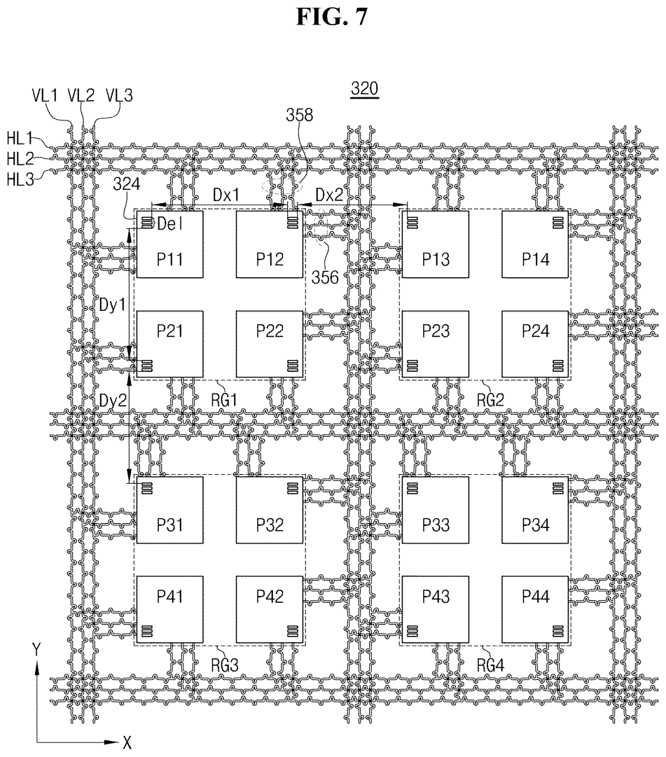

FIG. 7 is a plan view showing a display panel of a stretchable display device according to a an embodiment of the present disclosure. Illustrations on the same part as the first and an embodiments may be omitted.

In FIG. 7, a display panel 320 of a stretchable display device according to a an embodiment of the present disclosure includes a plurality of third substrates 324, a plurality of vertical lines VL1, VL2 and VL3 disposed between two of the plurality of third substrates 324 adjacent to each other along a first direction X, a plurality of horizontal lines HL1, HL2 and HL3 disposed between two of the plurality of third substrates 324 adjacent to each other along a second direction Y crossing the first direction X, a plurality of vertical connection lines 356 connecting the plurality of third substrates 324 and the plurality of vertical lines VL1, VL2 and VL3 and a plurality of horizontal connection lines 358 connecting the plurality of third substrates 324 and the plurality of horizontal lines HL1, HL2 and HL3.

Each of the plurality of third substrates 324 includes first, second and third subpixels SP1, SP2 and SP3 constituting a pixel, and each of the first, second and third subpixels SP1, SP2 and SP3 includes a light emitting diode Del.

Each of the plurality of third substrates 324 may have a tetragonal shape.

Four third substrates 324 of two rows and two columns adjacent to each other along the first and second directions X and Y constitute one rigid part group RG1, RG2, RG3 and RG4. The plurality of vertical lines VL1, VL2 and VL3 are disposed between two rigid part groups adjacent to each other along the first direction X, and the plurality of horizontal lines HL1, HL2 and HL3 are disposed between two rigid part groups adjacent to each other along the second direction Y.

For example, when the plurality of third substrates 324 includes first-first pixel P11 to fourth-fourth pixel P44 of 16 pixels which are disposed in four rows and four columns (e.g., the first-first pixel P11 is disposed at first row and first column, the second-third pixel P23 is disposed at second row and third column, and the fourth-fourth pixel P44 is disposed at fourth row and fourth column), the first-first pixel P11, the first-second pixel P12, the second-first pixel P21 and the second-second pixel P22 may constitute a first rigid part group RG1, the first-third pixel P13, the first-fourth pixel P14, the second-third pixel P23 and the second-fourth pixel P24 may constitute a second rigid part group RG2, the third-first pixel P31, the third-second pixel P32, the fourth-first pixel P41 and the fourth-second pixel P42 may constitute a third rigid part group RG3, and the third-third pixel P33, the third-fourth pixel P34, the fourth-third pixel P43 and the fourth-fourth pixel P44 may constitute a fourth rigid part group RG4.

The first, second and third vertical lines VL1, VL2 and VL3 may be disposed between the first and second rigid part groups RG1 and RG2 adjacent to each other along the first direction X and between the third and fourth rigid part groups RG3 and RG4 adjacent to each other along the first direction X. The first, second and third horizontal lines HL1, HL2 and HL3 may be disposed between the first and third rigid part groups RG1 and RG3 adjacent to each other along the second direction Y and between the second and fourth rigid part groups RG2 and RG4 adjacent to each other along the second direction Y.

Each first side of four third substrates 324 of each rigid part group RG1, RG2, RG3 and RG4 is connected to the plurality of vertical lines VL1, VL2 and VL3 through a plurality of vertical connection lines 356, and each first side of four third substrates 324 of each rigid part group RG1, RG2, RG3 and RG4 is connected to the plurality of horizontal lines HL1, HL2 and HL3 through a plurality of horizontal connection lines 358.

For example, a left side of the first-first pixel P11 of the first rigid part group RG1 may be connected to the plurality of vertical lines VL1, VL2 and VL3 at a left of the first-first pixel P11 of the first rigid part group RG1 through the plurality of vertical connection lines 356, and a top side adjacent to the left side of the first-first pixel P11 of the first rigid part group RG1 may be connected to the plurality of horizontal lines HL1, HL2 and HL3 at a top of the first-first pixel P11 of the first rigid part group RG1 through the plurality of horizontal connection lines 358.

A right side of the first-second pixel P12 of the first rigid part group RG1 may be connected to the plurality of vertical lines VL1, VL2 and VL3 at a right of the first-second pixel P12 of the first rigid part group RG1 through the plurality of vertical connection lines 356, and a top side adjacent to the right side of the first-second pixel P12 of the first rigid part group RG1 may be connected to the plurality of horizontal lines HL1, HL2 and HL3 at a top of the first-second pixel P12 of the first rigid part group RG1 through the plurality of horizontal connection lines 358.

A left side of the second-first pixel P21 of the first rigid part group RG1 may be connected to the plurality of vertical lines VL1, VL2 and VL3 at a left of the second-first pixel P21 of the first rigid part group RG1 through the plurality of vertical connection lines 356, and a bottom side adjacent to the left side of the second-first pixel P21 of the first rigid part group RG1 may be connected to the plurality of horizontal lines HL1, HL2 and HL3 at a bottom of the second-first pixel P21 of the first rigid part group RG1 through the plurality of horizontal connection lines 358.

A right side of the second-second pixel P22 of the first rigid part group RG1 may be connected to the plurality of vertical lines VL1, VL2 and VL3 at a right of the second-second pixel P22 of the first rigid part group RG1 through the plurality of vertical connection lines 356, and a bottom side adjacent to the right side of the second-second pixel P22 of the first rigid part group RG1 may be connected to the plurality of horizontal lines HL1, HL2 and HL3 at a bottom of the second-second pixel P22 of the first rigid part group RG1 through the plurality of horizontal connection lines 358.

Each of the first-third pixel P13, the first-fourth pixel P14, the second-third pixel P23 and the second-fourth pixel P24 of the second rigid part group RG2, the third-first pixel P31, the third-second pixel P32, the fourth-first pixel P41 and the fourth-second pixel P42 of the third rigid part group RG3, and the third-third pixel P33, the third-fourth pixel P34, the fourth-third pixel P43 and the fourth-fourth pixel P44 of the fourth rigid part group RG4 may be connected to the plurality of vertical lines VL1, VL2 and VL3 through the plurality of vertical connection lines 356 and may be connected to the plurality of horizontal lines HL1, HL2 and HL3 through the plurality of horizontal connection lines 358.

The plurality of vertical lines VL1, VL2 and VL3 are spaced apart from each other along the second direction Y to transmit a plurality of pixel driving voltages for driving the light emitting diode Del. The plurality of horizontal lines HL1, HL2 and HL3 are spaced apart from each other along the first direction X to transmit a plurality of pixel driving voltages for driving the light emitting diode Del.

For example, the plurality of vertical lines may include first, second and third vertical lines VL1, VL2 and VL3, and the first, second and third vertical lines VL1, VL2 and VL3 may transmit red, green and blue data voltages Vda, respectively. The plurality of horizontal lines may include first, second and third horizontal lines HL1, HL2 and HL3, and the first, second and third horizontal lines HL1, HL2 and HL3 may transmit a gate voltage Vsc, a high level voltage Vdd and a low level voltage Vss, respectively.

In an embodiment, the plurality of vertical lines may include first, second, third and fourth vertical lines, and the first, second, third and fourth vertical lines may transmit red, green and blue data voltages and a reference voltage, respectively. The plurality of horizontal lines may include first, second, third and fourth horizontal lines, and the first, second, third and fourth horizontal lines may transmit a gate voltage, a high level voltage, a low level voltage and an emission voltage, respectively.

Each of the plurality of vertical lines VL1, VL2 and VL3 and the plurality of horizontal lines HL1, HL2 and HL3 may have a wave shape, a diamond shape or a zigzag shape.

Each of the plurality of vertical connection lines 356 may be connected between the first side of each of the plurality of third substrates 324 and the plurality of vertical lines VL1, VL2 and VL3 along the first direction X to transmit the plurality of pixel driving voltages of the plurality of vertical lines VL1, VL2 and VL3 to each of the plurality of third substrates 324.

For example, the plurality of vertical connection lines 356 may include first, second and third vertical connection lines. The first vertical connection line may be connected to the first vertical line VL1 and the first subpixel SP1 to transmit the red data voltage Vda of the first vertical line VL1 to the first subpixel SP1, the second vertical connection line may be connected to the second vertical line VL2 and the second subpixel SP2 to transmit the green data voltage Vda of the second vertical line VL2 to the second subpixel SP2, and the third vertical connection line may be connected to the third vertical line VL3 and the third subpixel SP3 to transmit the blue data voltage Vda of the third vertical line VL3 to the third subpixel SP3.

The first vertical connection line may be connected to the first vertical line VL1. The second vertical connection line may cross the first vertical line VL1 in an electrically insulated state from the first vertical line VL1 to be connected to the second vertical line VL2. The third vertical connection line may cross the first and second vertical lines VL1 and VL2 in an electrically insulated state from the first and second vertical lines VL1 and VL2 to be connected to the third vertical line VL3.

Each of the plurality of horizontal connection lines 358 may be connected between the second side adjacent to the first side of each of the plurality of third substrates 324 and the plurality of horizontal lines HL1, HL2 and HL3 along the second direction Y to transmit the plurality of pixel driving voltages of the plurality of horizontal lines HL1, HL2 and HL3 to each of the plurality of third substrates 324.

For example, the plurality of horizontal connection lines 358 may include first, second and third horizontal connection lines. The first horizontal connection line may be connected to the first horizontal line HL1 and the first, second and third subpixels SP1, SP2 and SP3 to transmit the gate voltage Vsc of the first horizontal line HL1 to the first, second and third subpixels SP1, SP2 and SP3, the second horizontal connection line may be connected to the second horizontal line HL2 and the first, second and third subpixels SP1, SP2 and SP3 to transmit the high level voltage Vdd of the second horizontal line HL2 to the first, second and third subpixels SP1, SP2 and SP3, and the third horizontal connection line may be connected to the third horizontal line HL3 and the first, second and third subpixels SP1, SP2 and SP3 to transmit the low level voltage Vss of the third horizontal line HL3 to the first, second and third subpixels SP1, SP2 and SP3.

The first horizontal connection line may be connected to the first horizontal line HL1. The second horizontal connection line may cross the first horizontal line HL1 in an electrically insulated state from the first horizontal line HL1 to be connected to the second horizontal line HL2. The third horizontal connection line may cross the first and second horizontal lines HL1 and HL2 in an electrically insulated state from the first and second horizontal lines HL1 and HL2 to be connected to the third horizontal line HL3.

Each of the plurality of vertical connection lines 356 and the plurality of horizontal connection lines 358 may have a wave shape, a diamond shape or a zigzag shape.

The light emitting diodes Del of the first, second and third subpixels may be disposed at four corners of each rigid part group.

For example, in the first rigid part group RG1, the light emitting diodes Del may be disposed at a top-left corner of the first-first pixel P11, a top-right corner of the first-second pixel P12, a bottom-left corner of the second-first pixel P21 and a bottom-right corner of the second-second pixel P22.

Similarly, in the second rigid part group RG2, the light emitting diodes Del may be disposed at a top-left corner of the first-third pixel P13, a top-right corner of the first-fourth pixel P14, a bottom-left corner of the second-third pixel P23 and a bottom-right corner of the second-fourth pixel P24. In the third rigid part group RG3, the light emitting diodes Del may be disposed at a top-left corner of the third-first pixel P31, a top-right corner of the third-second pixel P32, a bottom-left corner of the fourth-first pixel P41 and a bottom-right corner of the fourth-second pixel P42. In the fourth rigid part group RG4, the light emitting diodes Del may be disposed at a top-left corner of the third-third pixel P33, a top-right corner of the third-fourth pixel P34, a bottom-left corner of the fourth-third pixel P43 and a bottom-right corner of the fourth-fourth pixel P44.

As a result, a first x gap distance Dx1 along the first direction X between the light emitting diode Del of the first-first pixel P11 of the first rigid part group RG1 and the light emitting diode Del of the first-second pixel P12 of the first rigid part group RG1 may be similar to or the same as a second x gap distance Dx2 along the first direction X between the light emitting diode Del of the first-second pixel P12 of the first rigid part group RG1 and the light emitting diode Del of the first-third pixel P13 of the second rigid part group RG2. A first y gap distance Dy1 along the second direction Y between the light emitting diode Del of the first-first pixel P11 of the first rigid part group RG1 and the light emitting diode Del of the second-first pixel P21 of the first rigid part group RG1 may be similar to or the same as a second y gap distance Dy2 along the second direction Y between the light emitting diode Del of the second-first pixel P21 of the first rigid part group RG1 and the light emitting diode Del of the third-first pixel P31 of the third rigid part group RG3.

Although the plurality of third substrates 324 are spaced apart from each other by the different distances along the first and second directions X and Y, the light emitting diodes Del are spaced apart from each other by the similar or same distance. Accordingly, lights emitted from the light emitting diodes Del have uniform distances, and a uniformity of an image displayed by the display panel 320 is improved.

In the display device according to a an embodiment of the present disclosure, the plurality of vertical lines VL1, VL2 and VL3 are disposed between the third substrates 324 of the rigid part adjacent to each other along the first direction X, and the plurality of horizontal lines HL1, HL2 and HL3 are disposed between the third substrates 324 of the rigid part adjacent to each other along the second direction Y. The plurality of vertical connection lines 356 connect a first side of the third substrate 324 of the rigid part and the plurality of vertical lines VL1, VL2 and VL3, and the plurality of horizontal connection lines 358 connect a second side of the third substrate 324 of the rigid part and the plurality of horizontal lines HL1, HL2 and HL3. Since the adjacent rigid parts are not connected to the horizontal line and the vertical line and have at least one side spaced apart from the horizontal line and the vertical line, a strain applied to the soft part is reduced and a stretch rate is maximized.

For example, when the display panel 320 is stretched by about 20%, each of the rigid part and the soft part may be stretched by about 20%. As a result, a stretch reliability is improved.

Four adjacent third substrates 324 along the first and second directions X and Y are classified as one rigid part group. The plurality of vertical lines VL1, VL2 and VL3 are disposed between two adjacent rigid part groups along the first direction X, and the plurality of horizontal lines HL1, HL2 and HL3 are disposed between two adjacent rigid part groups along the second direction Y. The plurality of vertical connection lines 356 connect the first side of the third substrate 324 of the rigid part and the plurality of vertical lines VL1, VL2 and VL3, and the plurality of horizontal connection lines 358 connect the second side of the third substrate 324 of the rigid part and the plurality of horizontal lines HL1, HL2 and HL3. As a result, the rigid part and the soft part have an area ratio of about 2:1. Since the area ratio of the rigid part increases, a degree of freedom for a design of a relatively high resolution increases.

Further, since the light emitting diodes Del are disposed at the corners of each rigid part group, the light emitting diodes have the similar or same gap distance. As a result, lights emitted from the light emitting diodes Del have uniform distances, and a uniformity of an image displayed by the display panel 320 is improved.

In the description herein, voltage lines (vertical voltage lines VL and horizontal voltage lines HL) are described as examples of signals lines corresponding to or connected to the unit substrates 124. The similar descriptions may also apply to other signal lines like gate lines or data lines as will be appreciated by people having ordinary skill in the art, which are all included in the scope of the disclosure.

It will be apparent to those skilled in the art that various modifications and variation can be made in the present disclosure without departing from the scope of the disclosure. Thus, it is intended that the present disclosure cover the modifications and variations of this disclosure including those of the appended claims.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a first substrate and a second substrate facing and spaced apart from each other;
a plurality of third substrates on an inner surface of the first substrate that faces the second substrate, the plurality of third substrates spaced apart from each other;
a plurality of vertical lines each between two of the plurality of third substrates adjacent to each other along a first direction;
a plurality of horizontal lines each between two of the plurality of third substrates adjacent to each other along a second direction crossing the first direction;
a plurality of vertical connection lines each connecting a first side of one of the plurality of third substrates and a vertical line of the plurality of vertical lines;
a plurality of horizontal connection lines each connecting a second side of one of the plurality of third substrates and a horizontal line of the plurality of horizontal lines, a second side of a third substrate adjacent to a first side of the third substrate; and
a plurality of light emitting diodes on the plurality of third substrates, respectively.

2. The display device of claim 1, wherein a third substrate of the plurality of third substrates includes at least one side spaced apart from the plurality of vertical lines and the plurality of horizontal lines.

3. The display device of claim 1, wherein the first substrate and second substrate include a soft material, and the plurality of third substrates each include a rigid material.

4. The display device of claim 1, wherein the plurality of vertical lines, the plurality of horizontal lines, the plurality of vertical connection lines and the plurality of horizontal connection lines each have one of a wave shape, a diamond shape or a zigzag shape.

5. The display device of claim 1, wherein the plurality of vertical lines includes a first vertical line, a second vertical line, and a third vertical line,
wherein the plurality of horizontal lines includes a first horizontal line, a second horizontal line, and a third horizontal line,
wherein the plurality of vertical connection lines include a first vertical connection line, a second vertical connection line, and a third vertical connection line,
wherein the plurality of horizontal connection lines include a first horizontal connection line, a second horizontal connection line, and a third horizontal connection line,
wherein the first vertical connection line is connected to a first side of a third substrate of the plurality of third substrates and the first vertical line,
wherein the second vertical connection line is connected to the first side of the third substrate of the plurality of third substrates and the second vertical line,
wherein the third vertical connection line is connected to the first side of the third substrate of the plurality of third substrates and the third vertical line,
wherein the first horizontal connection line is connected to a second side of the third substrate adjacent to the first side of the third substrate of the plurality of third substrates and the first horizontal line,
wherein the second horizontal connection line is connected to the second side of the third substrate of the plurality of third substrates and the second horizontal line, and
wherein the third horizontal connection line is connected to the second side of the third substrate of the plurality of third substrates and the third horizontal line.

6. The display device of claim 5, wherein a cross insulating layer disposed under the first and second vertical lines and the first and second horizontal lines, and a bridge layer disposed under the cross insulating layer,
wherein the first vertical connection line is connected between the first side of the third substrate of the plurality of third substrates and the first vertical line without the bridge layer therebetween,
wherein the second vertical connection line is connected between the first side of the third substrate of the plurality of third substrates and a first side of the bridge layer under the first vertical line and between a second side of the bridge layer under the first vertical line and the second vertical line,
wherein the third vertical connection line is connected between the first side of the third substrate of the plurality of third substrates and the first side of the bridge layer under the first vertical line, between the second side of the bridge layer under the first vertical line and a first side of the bridge layer under the second vertical line and between a second side of the bridge layer under the second vertical line and the third vertical line,
wherein the first horizontal connection line is connected between the second side of the third substrate of the plurality of third substrates and the first horizontal line without the bridge layer therebetween,
wherein the second horizontal connection line is connected between the second side of the third substrate of the plurality of third substrates and a third side of the bridge layer under the first horizontal line and between a fourth side of the bridge layer under the first horizontal line and the second horizontal line, and
wherein the third horizontal connection line is connected between the second side of the third substrate of the plurality of third substrates and the third side of the bridge layer under the first horizontal line, between the fourth side of the bridge layer under the first horizontal line and a third side of the bridge layer under the second horizontal line and between a fourth side of the bridge layer under the second horizontal line and the third horizontal line.

7. The display device of claim 5, wherein a cross insulating layer is disposed under the first, second and third vertical lines and on the first, second and third horizontal lines,
wherein the first vertical connection line is connected to the first side of the third substrate of the plurality of third substrates and is connected to the first vertical line through a first contact hole in the cross insulating layer,
wherein the second vertical connection line is connected to the first side of the third substrate of the plurality of third substrates and is connected to the second vertical line through a second contact hole in the cross insulating layer,
wherein the third vertical connection line is connected to the first side of the third substrate of the plurality of third substrates and is connected to the third vertical line through a third contact hole in the cross insulating layer,
wherein the first horizontal connection line is connected to the second side of the third substrate of the plurality of third substrates and is connected to the first horizontal line through a fourth contact hole in the cross insulating layer,
wherein the second horizontal connection line is connected to the second side of the third substrate of the plurality of third substrates and is connected to the second horizontal line through a fifth contact hole in the cross insulating layer, and
wherein the third horizontal connection line is connected to the second side of the third substrate of the plurality of third substrates and is connected to the third horizontal line through a sixth contact hole in the cross insulating layer.

8. The display device of claim 1, wherein the plurality of third substrates includes a plurality of rigid part groups, each rigid part group having four third substrates arranged in two rows and two columns,
wherein the plurality of vertical lines are disposed between two rigid part groups adjacent to each other along the first direction, and
wherein the plurality of horizontal lines are disposed between two rigid groups adjacent to each other along the second direction.

9. The display device of claim 8, wherein the plurality of third substrates include a first-first pixel to a fourth-fourth pixel in four rows and four columns,
wherein the first-first pixel, the first-second pixel, the second-first pixel and the second-second pixel constitute a first rigid part group, the first-third pixel, the first-fourth pixel, the second-third pixel and the second-fourth pixel constitute a second rigid part group, the third-first pixel, the third-second pixel, the fourth-first pixel and the fourth-second pixel constitute a third rigid part group, and the third-third pixel, the third-fourth pixel, the fourth-third pixel and the fourth-fourth pixel constitute a fourth rigid part group,
wherein the plurality of vertical lines are disposed at a first side of the first and third rigid part groups, between the first and third rigid part groups and the second and fourth rigid part groups and at a second side of the second and fourth rigid part groups, the first side and the second side opposite to one another, and
wherein the plurality of horizontal lines are disposed at a third side of the first and second rigid part groups, between the first and second rigid part groups and the third and fourth rigid part groups and at a fourth side of the third and fourth rigid part groups, the third side and the fourth side opposite to one another.

10. The display device of claim 9, wherein the plurality of vertical connection lines connect:
first sides of the first-first pixel, the second-first pixel, the third-first pixel and the fourth-first pixel and the plurality of vertical lines at the first side of the first and third rigid part groups,
second sides of the first-second pixel, the second-second pixel, the third-second pixel and the fourth-second pixel and the plurality of vertical lines between the first and third rigid part groups and between the second and fourth rigid part groups,
first sides of the first-third pixel, the second-third pixel, the third-third pixel and the fourth-third pixel and the plurality of vertical lines between the first and third rigid part groups and between the second and fourth rigid part groups, and
second sides of the first-fourth pixel, the second-fourth pixel, the third-fourth pixel and the fourth-fourth pixel and the plurality of vertical lines at the second side of the second and fourth rigid part groups, and
wherein the plurality of horizontal connection lines connect:
third sides of the first-first pixel, the first-second pixel, the first-third pixel and the first-fourth pixel and the plurality of horizontal lines at the third side of the first and second rigid part groups,
fourth sides of the second-first pixel, the second-second pixel, the second-third pixel and the second-fourth pixel and the plurality of horizontal lines between the first and second rigid part groups and between the third and fourth rigid part groups,
third sides of the third-first pixel, the third-second pixel, the third-third pixel and the third-fourth pixel and the plurality of horizontal lines between the first and second rigid part groups and between the third and fourth rigid part groups, and
fourth sides of the fourth-first pixel, the fourth-second pixel, the fourth-third pixel and the fourth-fourth pixel and the plurality of horizontal lines at a the fourth side of the third and fourth rigid part groups.

11. The display device of claim 8, wherein the plurality of light emitting diodes are disposed at a corner of the rigid part group.

12. The display device of claim 11, wherein the plurality of third substrates include a first-first pixel, a first-second pixel, a second-first pixel and a second-second pixel in two rows and two columns, and
wherein the plurality of light emitting diodes are disposed at a first corner of the first-first pixel where a first side and a third side of the first-first pixel meet, at a second corner of the first-second pixel where a second side and a third side of the first-second pixel meet, at a third corner of the second-first pixel where a first side and a fourth side of the second-first pixel meet, and at a fourth corner of the second-second pixel where a second side and a fourth side of the second-second pixel meet.

13. The display device of claim 12, wherein a first gap distance between adjacent two of the plurality of light emitting diodes and a second gap distance between another adjacent two of the plurality of light emitting diodes are a same as each other.

14. A display device, comprising:
a base substrate having a first material;
a plurality of unit substrates on a first surface of the base substrate, the plurality of unit substrates spaced apart from each other and each having a second material different from the first material;
a plurality of signal lines each extending along a first direction and between a first unit substrate and a second unit substrate of the plurality of unit substrates, the first unit substrate and the second unit substrate adjacent to each other in a second direction that crosses the first direction; and
a plurality of first connection lines each connecting one of the plurality of signal lines to the first unit substrate.

15. The display device of claim 14, wherein the plurality of signal lines are not connected to the second unit substrate.

16. The display device of claim 14, comprising a plurality of second connection lines each connecting one of the plurality of signal lines to the second unit substrate.

17. The display device of claim 14, wherein the second material has a Young's modulus value equal to or greater than 1000 times of a Young's modulus value of the first material.

18. A structure comprising:
a base substrate;
a unit substrate on the base substrate, the base substrate extending beyond the unit substrate from each side of the unit substrate, the unit substrate including a circuit unit;
a first signal line on the base substrate and spaced apart from the unit substrate; and
a connection line connected between the circuit unit and the first signal line, the connection line extending along a sidewall of the unit substrate and beyond the unit substrate toward the first signal line.

19. The structure of claim 18, further comprising:
a second signal line positioned between the first signal line and the unit substrate, and spaced apart from both the first signal line and the unit substrate;
an insulation layer below the second signal line; and
a bridge layer below the insulation layer,
wherein the connection line is connected to the first signal line via the bridge layer and the connection line is insulated from the second signal line by the insulation layer.

20. The structure of claim 18, further comprising:
a second signal line positioned between the first signal line and the unit substrate, and spaced apart from both the first signal line and the unit substrate;
an insulation layer below the second signal line, the insulation layer including a hole,
wherein the connection line extends below the insulation layer and is connected to the first signal line through the hole.
